(19) United States
(12) Patent Application Publication
(10) Pub. No.: US 2026/0073099 A1
(43) Pub. Date: Mar. 12, 2026

(54) PROPERTY GUIDED MOLECULAR OPTIMIZATION USING ARTIFICIAL INTELLIGENCE DIFFUSION MODELS

(71) Applicant: NEC Laboratories America, Inc., Princeton, NJ (US)

(72) Inventors: Tianxiao Li, Plainsboro, NJ (US); Renqiang Min, Princeton, NJ (US)

(21) Appl. No.: 19/321,736

(22) Filed: Sep. 8, 2025

Related U.S. Application Data
(60) Provisional application No. 63/692,805, filed on Sep. 10, 2024.
(60) Provisional application No. 63/736,099, filed on Dec. 19, 2024.

(51) Int. Cl. G06F 30/27

(52) U.S. Cl. CPC G06F 30/27

(57) ABSTRACT

Systems and methods for property guided molecular optimization using artificial intelligence diffusion models. An equivariant continuous denoising diffusion implicit model autoencoder framework (DDIM-AE) can be trained on a conformational dataset to predict raw data from data corrupted by a time-dependent noise to obtain a trained DDIM-AE that ensures controlled generation of three-dimensional (3D) molecules. Linear optimization of semantic embeddings of 3D molecules can be performed with a linear classifier to achieve a target property value from desired properties and obtain an optimized embedding. An optimized 3D molecule that includes molecular conformation with the desired properties while preserving interactions with biochemical molecules can be generated from the optimized embedding with the trained DDIM-AE.

### RELATED APPLICATION INFORMATION

This application claims priority to U.S. Provisional App. No. 63/692,805, filed on Sep. 10, 2024, and to U.S. Provisional App. No. 63/736,099, filed on Dec. 19, 2024, incorporated herein by reference in its entirety.

### BACKGROUND

### Technical Field

The present invention relates to three-dimensional (3D) molecule optimization with artificial intelligence (AI), and more particularly to property guided molecular optimization using artificial intelligence diffusion models.

### Description of the Related Art

Computational design of molecules has many applications in drug design and protein engineering. The 3D geometry of molecules holds significant implications for their properties and functions, such as quantum chemical properties, molecular dynamics, and interactions with protein receptors. Recently, generative modeling of 3D molecules has been an active area of research.

### SUMMARY

According to an aspect of the present invention, a method is provided including training an equivariant continuous denoising diffusion implicit model autoencoder framework (DDIM-AE) on a conformational dataset to predict raw data from data corrupted by a time-dependent noise to obtain a trained DDIM-AE, performing linear optimization of semantic embeddings of three-dimensional (3D) molecules with a linear classifier to achieve a target property value from desired properties and obtain an optimized embedding, and generating an optimized 3D molecule that includes molecular conformation with the desired properties while preserving interactions with biochemical molecules from the optimized embedding with the trained DDIM-AE.

According to another aspect of the present invention, a system is provided including a memory device, one or more processor devices operatively coupled with the memory device to perform operations, training an equivariant continuous denoising diffusion implicit model autoencoder framework (DDIM-AE) on a conformational dataset to predict raw data from data corrupted by a time-dependent noise to obtain a trained DDIM-AE that ensures controlled generation of three-dimensional (3D) molecules, performing linear optimization of semantic embeddings of 3D molecules with a linear classifier to achieve a target property value from desired properties and obtain an optimized embedding, and generating an optimized 3D molecule that includes molecular conformation with the desired properties while preserving interactions with biochemical molecules from the optimized embedding with the trained DDIM-AE.

According to yet another aspect of the present invention, a non-transitory computer program product is provided including a computer-readable storage medium including a program code, wherein the program code when executed on a computer causes the computer to perform, training an equivariant continuous denoising diffusion implicit model autoencoder framework (DDIM-AE) on a conformational dataset to predict raw data from data corrupted by a time-dependent noise to obtain a trained DDIM-AE that ensures controlled generation of three-dimensional (3D) molecules, performing linear optimization of semantic embeddings of 3D molecules with a linear classifier to achieve a target property value from desired properties and obtain an optimized embedding, and generating an optimized 3D molecule that includes molecular conformation with the desired properties while preserving interactions with biochemical molecules from the optimized embedding with the trained DDIM-AE.

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1 is a block diagram showing a system for property guided molecular optimization using artificial intelligence diffusion models, in accordance with one embodiment of the present invention;

FIG. 2 is a block diagram showing a computer system implementing property guided molecular optimization using artificial intelligence diffusion models, in accordance with an embodiment of the present invention;

FIG. 3 is a block diagram showing hardware and software components utilized for training the denoising diffusion implicit model autoencoder framework (DDIM-AE), in accordance with an embodiment of the present invention;

FIG. 4 is a block diagram showing hardware and software components utilized for generating an optimized three-dimensional molecule by utilizing the trained denoising diffusion implicit model autoencoder framework (DDIM-AE), in accordance with an embodiment of the present invention; and

FIG. 5 is a flow diagram showing a high-level overview of a method for property guided molecular optimization using artificial intelligence diffusion models, in accordance with an embodiment of the present invention.

### DETAILED DESCRIPTION OF PREFERRED EMBODIMENTS

In accordance with embodiments of the present invention, systems and methods are provided for property guided molecular optimization using artificial intelligence diffusion models.

In the present embodiments, an equivariant continuous denoising diffusion implicit model autoencoder framework (DDIM-AE) can be trained on a conformational dataset to predict raw data from data corrupted by a time-dependent noise to obtain a trained DDIM-AE that ensures controlled generation of three-dimensional (3D) molecules. Linear optimization of semantic embeddings of 3D molecules can be performed with a linear classifier to achieve a target property value from desired properties and obtain an optimized embedding. An optimized 3D molecule that includes molecular conformation with the desired properties while preserving interactions with biochemical molecules can be generated from the optimized embedding with the trained DDIM-AE.

Computational design of molecules includes the processing of input molecules to determine compatibility of the input molecules with desired properties. This process can include proper representation of the 3D geometry of the input molecules. To determine the proper representation of the 3D geometry of the input molecules, some methods learning a joint distribution between geometric features. Other methods directly operate on the 3D molecular space.

More recently, equivariant diffusion models have achieved state-of-the-art results in generating high-quality 3D molecules, and in designing tasks with external conditioning, such as ligands given protein receptors and linkers given molecular fragments. Diffusion models belong to the class of generative models designed to approximate the data distribution by iteratively removing noise. Unlike previous methods for molecule generation that rely on autoregressive generation, diffusion models perform simultaneous refinement of all elements, such as atoms, in each denoising iteration. This collective refinement approach enables them to effectively capture the underlying data structures, making them well-suited for structured generation such as 3D molecules.

Several recent studies further incorporate auxiliary information, such as bond connectivity, to improve the generation quality. However, the majority of these works focus on de novo generation, i.e., generating random 3D molecules with no or limited control on their compositions, structures and properties.

In real world applications such as drug design, it is desirable to ensure the generated molecules contain certain components, structural patterns of properties through explicit controls on the generation process. Some previous works focus on the controlled generation of two-dimensional (2D) graphs. However, controlling 3D molecule generation remains a challenge due to the complexity of the 3D molecular space and the need of preserving the 3D geometry.

Some recent studies have attempted to control 3D molecule generative models by conditioning on single properties or 3D shapes. These methods, despite being effective on the designated tasks, only control a narrow portion of the generation process, and cannot be easily generalized to multiple or novel conditions without re-training a conditional diffusion model.

On the other hand, it is uncertain how properties impact each other as a result of the conditioning due to their complex interplays, and manually separating them is non-trivial and time-consuming. For example, improving the water solubility (lower octanol-water partition coefficient (Log P)) could be achieved by adding hydroxyl groups or halogens. As a result, methods solely targeting lower Log P may use either direction to fulfill this task. However, in real applications, there could also be requirements on the number of halogens, which cannot be fulfilled by these methods. The task becomes more challenging with more requirements on other properties, such as overall 3D shape, or the interaction with protein receptors.

Controllable generation on diffusion models particularly poses another challenge as these models lack an explicit latent space to operate on. The latent diffusion model is trained on the low-dimensional latent space of another generative model, but the latent space of the diffusion model is still implicit and difficult to control. Thus, controllable generation is usually achieved by external guidance on the denoising process. For example, classifier guidance and classifier-free guidance could generate random samples conditioned on labels and continuous properties. These methods have high demands on the availability of labelled data, and extend poorly to multiple conditions. Some studies utilize external, pre-trained molecular representations as conditions. Though such representations could be highly informative, there is no theoretical guarantee of their control on the diffusion model, and they are also difficult to directly manipulate. Thus, for data-efficient control on multiple molecular properties, an unsupervised latent space that captures the complete information about molecular structures and compositions can be leveraged.

The present embodiments provides a disentangled autoencoding equivariant diffusion model controlled by an unsupervised, higher-level semantics embedding of the molecule. The present embodiments learn a semantic embedding of 3D molecules with a generation encoder and use it to control an equivariant diffusion model. The semantic embedding includes features that addresses at least the following challenges: maximal mutual information with the input that guarantees complete information about the molecule; strong control on the generation process of the diffusion model that effectively translates the semantics into the 3D molecular space; and disentangled dimensions which enables conditioning on multiple properties without contradictions between them. By directly operating on the semantics embedding, the present embodiments can control and manipulate multiple compositional and geometric properties, both individually and jointly.

Embodiments described herein may be entirely hardware, entirely software or including both hardware and software elements. In a preferred embodiment, the present invention is implemented in software, which includes but is not limited to firmware, resident software, microcode, etc.

Embodiments may include a computer program product accessible from a computer-usable or computer-readable medium providing program code for use by or in connection with a computer or any instruction execution system. A computer-usable or computer readable medium may include any apparatus that stores, communicates, propagates, or transports the program for use by or in connection with the instruction execution system, apparatus, or device. The medium can be magnetic, optical, electronic, electromagnetic, infrared, or semiconductor system (or apparatus or device) or a propagation medium. The medium may include a computer-readable storage medium such as a semiconductor or solid state memory, magnetic tape, a removable computer diskette, a random access memory (RAM), a read-only memory (ROM), a rigid magnetic disk and an optical disk, etc.

Each computer program may be tangibly stored in a machine-readable storage media or device (e.g., program memory or magnetic disk) readable by a general or special purpose programmable computer, for configuring and controlling operation of a computer when the storage media or device is read by the computer to perform the procedures described herein. The inventive system may also be considered to be embodied in a computer-readable storage medium, configured with a computer program, where the storage medium so configured causes a computer to operate in a specific and predefined manner to perform the functions described herein.

A data processing system suitable for storing and/or executing program code may include at least one processor coupled directly or indirectly to memory elements through a system bus. The memory elements can include local memory employed during actual execution of the program code, bulk storage, and cache memories which provide temporary storage of at least some program code to reduce the number of times code is retrieved from bulk storage during execution. Input/output or I/O devices (including but not limited to keyboards, displays, pointing devices, etc.) may be coupled to the system either directly or through intervening I/O controllers.

Network adapters may also be coupled to the system to enable the data processing system to become coupled to other data processing systems or remote printers or storage devices through intervening private or public networks. Modems, cable modem and Ethernet cards are just a few of the currently available types of network adapters.

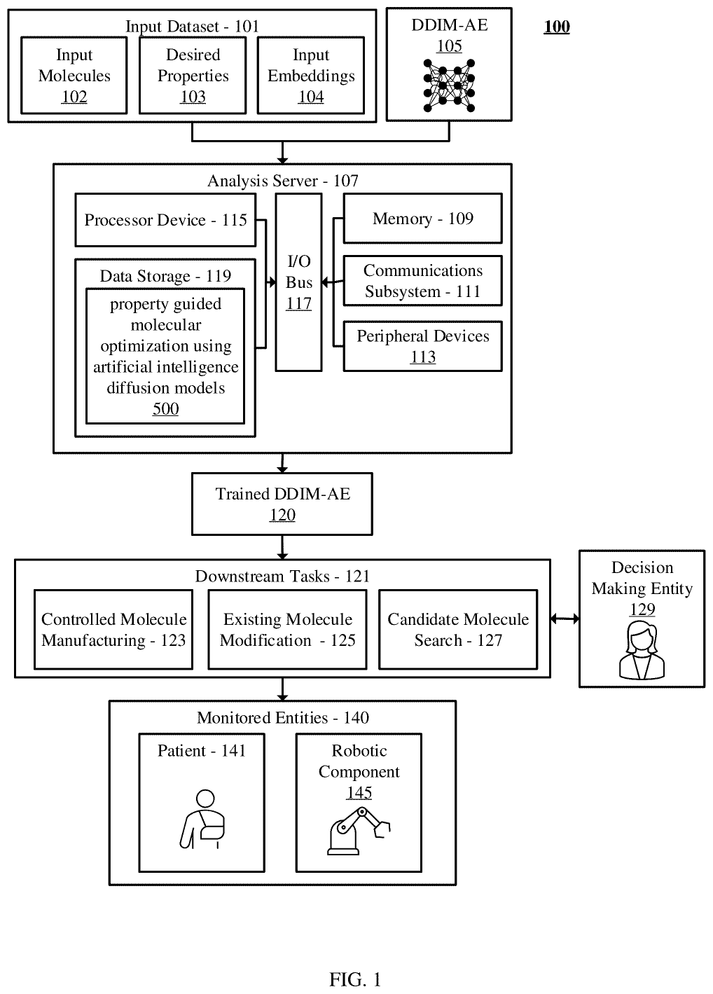

Referring now in detail to the figures in which like numerals represent the same or similar elements and initially to FIG. 1, a block diagram showing a system for property guided molecular optimization using artificial intelligence diffusion models, in accordance with one embodiment of the present invention.

In an embodiment, system 100 can process an input dataset 101 with an analysis server 107 that can implement property guided molecular optimization using artificial intelligence diffusion models 400 to train a denoising diffusion implicit model autoencoder framework (DDIM-AE) 105 to obtain a trained DDIM-AE 120 to perform downstream tasks 121 for monitored entities 140 to assist the decision-making process of a decision-making entity 129. The input dataset 101 can include input molecules 102, desired properties 103, and input embeddings 104 for the input molecules 102.

The downstream tasks 121 can include controlled molecule manufacturing 123, existing molecule modification 125, and candidate molecule search 127.

In controlled molecule manufacturing 123, the input dataset 101 can include input molecules 102 (e.g., ligand-receptor pairs, etc.) and input embeddings 104 of the input molecules 102 to generate optimized 3D molecules that can include the desired properties 103 (e.g., compositional and 3D shape properties). The desired properties 103 can also include a desired binding that can be used to perform further downstream tasks such as generating a drug that utilizes the desired binding for patient 141, generating a material based on the desired binding that can be used for semiconductor applications such as a circuit for robotic component 143, etc.

In existing molecule modification 125, the input dataset 101 can include input molecules 102 (e.g., ligand-receptor pairs, etc.) and input embeddings 104 of the input molecules 102 to modify the input molecules 102 with desired properties 103. For example, a molecule determined to be effective for lowering blood glucose levels of patient 141 can be modified to have faster absorption rates compared to the original molecule.

In candidate molecule search 127, the input molecules 102 can be simulated for 2D manipulation to search candidate molecules having desired properties 103 or compatibility with desired properties 103 from the input dataset 101 while preserving the 3D shape of the molecules. The input molecules 102 can be processed further for downstream tasks such as generating a drug that utilizes the desired binding (e.g., desired effect for patient 141 such as lowering blood sugar, lowering blood pressure, etc.), generating a material based on the desired binding (e.g., molecular orbital energy and polarizability, etc.) that can be used for semiconductor applications (e.g., quantum circuits for robotic component 143), notifying a decision-making entity 129 regarding a medical diagnosis for the patient based on desired bindings (e.g., existence of a disease, desired effect of a given drug, etc.) from the optimized 3D molecule, etc.

Other practical applications are contemplated.

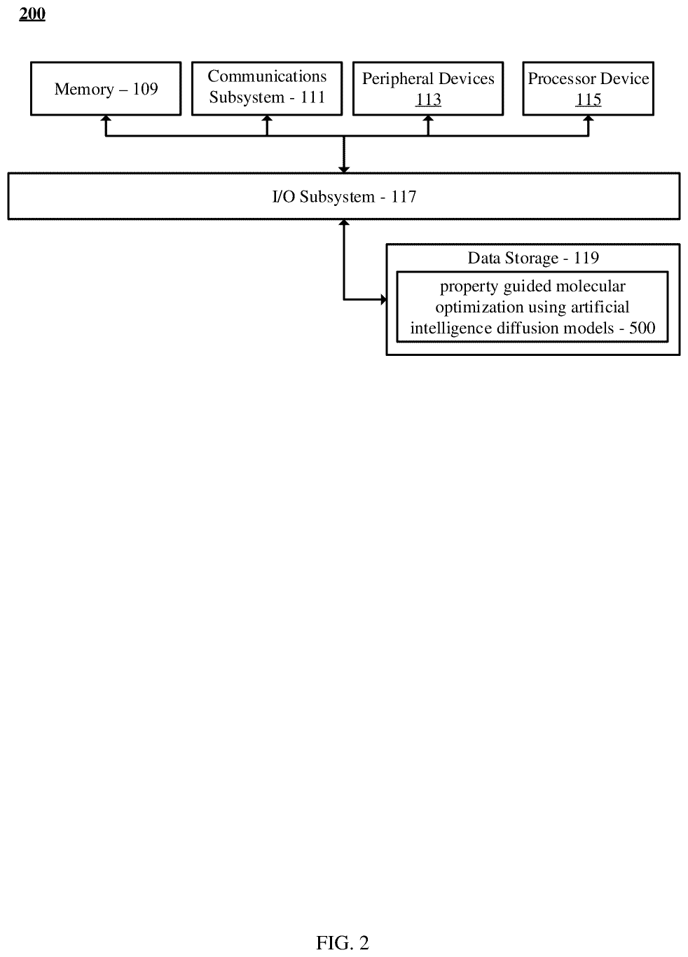

The analysis server 107 can include a memory 109, communications subsystem 111, peripheral devices 113, a processor device 115, input/output (I/O) bus 117, and data storage device 119. This is shown in more detail in FIG. 2.

Referring now to FIG. 2, a block diagram showing a computer system implementing property guided molecular optimization using artificial intelligence diffusion models, in accordance with an embodiment of the present invention.

In an embodiment, computing device 200 can be implemented as analysis server 107. The computing device 200 illustratively includes the processor device 115, an input/output (I/O) subsystem 117, a memory 109, a data storage device 119, and a communications subsystem 111, and/or other components and devices commonly found in a server or similar computing device. The computing device 200 may include other or additional components, such as those commonly found in a server computer (e.g., various input/output devices), in other embodiments. Additionally, in some embodiments, one or more of the illustrative components may be incorporated in, or otherwise form a portion of, another component. For example, the memory 109, or portions thereof, may be incorporated in the processor device 115 in some embodiments.

The processor device 115 may be embodied as any type of processor capable of performing the functions described herein. The processor device 115 may be embodied as a single processor, multiple processors, a Central Processing Unit(s) (CPU(s)), a Graphics Processing Unit(s) (GPU(s)), a single or multi-core processor(s), a digital signal processor(s), a microcontroller(s), or other processor(s) or processing/controlling circuit(s).

The memory 109 may be embodied as any type of volatile or non-volatile memory or data storage capable of performing the functions described herein. In operation, the memory 109 may store various data and software employed during operation of the computing device 200, such as operating systems, applications, programs, libraries, and drivers. The memory 109 is communicatively coupled to the processor device 115 via the I/O subsystem 117, which may be embodied as circuitry and/or components to facilitate input/output operations with the processor device 115, the memory 109, and other components of the computing device 200. For example, the I/O subsystem 117 may be embodied as, or otherwise include, memory controller hubs, input/output control hubs, platform controller hubs, integrated control circuitry, firmware devices, communication links (e.g., point-to-point links, bus links, wires, cables, light guides, printed circuit board traces, etc.), and/or other components and subsystems to facilitate the input/output operations. In some embodiments, the I/O subsystem 117 may form a portion of a system-on-a-chip (SOC) and be incorporated, along with the processor device 115, the memory 109, and other components of the computing device 200, on a single integrated circuit chip.

The data storage device 119 may be embodied as any type of device or devices configured for short-term or long-term storage of data such as, for example, memory devices and circuits, memory cards, hard disk drives, solid state drives, or other data storage devices. The data storage device 119 can store program code property guided molecular optimization using artificial intelligence diffusion models 400. Any or all of these program code blocks may be included in a given computing system.

The communications subsystem 111 of the computing device 200 may be embodied as any network interface controller or other communication circuit, device, or collection thereof, capable of enabling communications between the computing device 200 and other remote devices over a network. The communications subsystem 111 may be configured to employ any one or more communication technology (e.g., wired or wireless communications) and associated protocols (e.g., Ethernet, InfiniBand®, Bluetooth®, Wi-Fi®, WiMAX, etc.) to effect such communication.

As shown, the computing device 200 may also include one or more peripheral devices 113. The peripheral devices 113 may include any number of additional input/output devices, interface devices, and/or other peripheral devices. For example, in some embodiments, the peripheral devices 113 may include a display, touch screen, graphics circuitry, keyboard, mouse, speaker system, microphone, network interface, and/or other input/output devices, interface devices, GPS, camera, and/or other peripheral devices.

Of course, the computing device 200 may also include other elements (not shown), as readily contemplated by one of skill in the art, as well as omit certain elements. For example, various other sensors, input devices, and/or output devices can be included in computing device 200, depending upon the particular implementation of the same, as readily understood by one of ordinary skill in the art. For example, various types of wireless and/or wired input and/or output devices can be employed. Moreover, additional processors, controllers, memories, and so forth, in various configurations can also be utilized. These and other variations of the computing device 200 are readily contemplated by one of ordinary skill in the art given the teachings of the present invention provided herein.

As employed herein, the term “hardware processor subsystem” or “hardware processor” can refer to a processor, memory, software or combinations thereof that cooperate to perform one or more specific tasks. In useful embodiments, the hardware processor subsystem can include one or more data processing elements (e.g., logic circuits, processing circuits, instruction execution devices, etc.). The one or more data processing elements can be included in a central processing unit, a graphics processing unit, and/or a separate processor- or computing element-based controller (e.g., logic gates, etc.). The hardware processor subsystem can include one or more on-board memories (e.g., caches, dedicated memory arrays, read only memory, etc.). In some embodiments, the hardware processor subsystem can include one or more memories that can be on or off board or that can be dedicated for use by the hardware processor subsystem (e.g., ROM, RAM, basic input/output system (BIOS), etc.).

In some embodiments, the hardware processor subsystem can include and execute one or more software elements. The one or more software elements can include an operating system and/or one or more applications and/or specific code to achieve a specified result.

In other embodiments, the hardware processor subsystem can include dedicated, specialized circuitry that performs one or more electronic processing functions to achieve a specified result. Such circuitry can include one or more application-specific integrated circuits (ASICs), field-programmable gate arrays (FPGAs), and/or programmable logic arrays (PLAs).

These and other variations of a hardware processor subsystem are also contemplated in accordance with embodiments of the present invention.

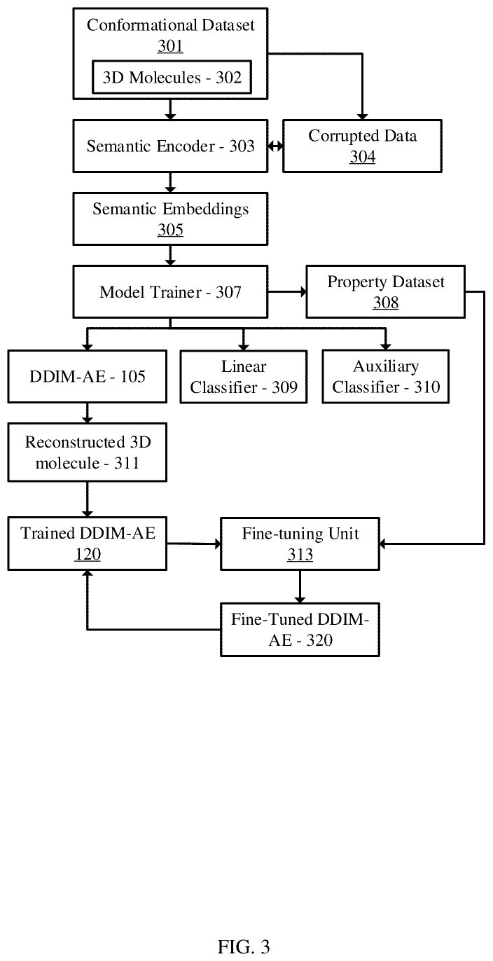

Referring now to FIG. 3, a block diagram showing hardware and software components utilized for training the denoising diffusion implicit model autoencoder framework (DDIM-AE), in accordance with an embodiment of the present invention.

In an embodiment, during training, a conformational dataset 301 can be processed by a semantic encoder 303 to generate semantic embeddings 305 for 3D molecules 302 in the conformational dataset 301. A model trainer 307 can train the DDIM-AE 105 to obtain a trained DDIM-AE 120 using the semantic embeddings 305. The DDIM-AE 105 can be trained to reconstruct the 3D molecules 302 and generate reconstructed 3D molecule 311 from the semantic embeddings 305. The trained DDIM-AE 105 is obtained when the reconstructed 3D molecule 311 is within an acceptable threshold based on a loss function (e.g., Wasserstein loss, reconstruction loss, etc.). The model trainer 307 can also generate a property dataset 308 for fine-tuning the trained DDIM-AE 120 with a fine-tuning unit 313 and obtain a fine-tuned DDIM-AE 320.

The model trainer 307 can also train a linear classifier 309 and an auxiliary classifier 310 to understand invariant features (e.g., atom types, edge types and pairwise distances) from the semantic embeddings 305 based on the conformational dataset 301.

The DDIM-AE 105, linear classifier 309 and auxiliary classifier 310 can utilize neural networks.

A neural network is a generalized system that improves its functioning and accuracy through exposure to additional empirical data. The neural network becomes trained by exposure to the empirical data. During training, the neural network stores and adjusts a plurality of weights that are applied to the incoming empirical data. By applying the adjusted weights to the data, the data can be identified as belonging to a particular predefined class from a set of classes or a probability that the inputted data belongs to each of the classes can be output.

The empirical data, also known as training data, from a set of examples can be formatted as a string of values and fed into the input of the neural network. Each example may be associated with a known result or output. Each example can be represented as a pair, (x, y), where x represents the input data and y represents the known output. The input data may include a variety of different data types and may include multiple distinct values. The network can have one input neurons for each value making up the example's input data, and a separate weight can be applied to each input value. The input data can, for example, be formatted as a vector, an array, or a string depending on the architecture of the neural network being constructed and trained.

The neural network “learns” by comparing the neural network output generated from the input data to the known values of the examples and adjusting the stored weights to minimize the differences between the output values and the known values. The adjustments may be made to the stored weights through back propagation, where the effect of the weights on the output values may be determined by calculating the mathematical gradient and adjusting the weights in a manner that shifts the output towards a minimum difference. This optimization, referred to as a gradient descent approach, is a non-limiting example of how training may be performed. A subset of examples with known values that were not used for training can be used to test and validate the accuracy of the neural network.

During operation, the trained neural network can be used on new data that was not previously used in training or validation through generalization. The adjusted weights of the neural network can be applied to the new data, where the weights estimate a function developed from the training examples. The parameters of the estimated function which are captured by the weights are based on statistical inference.

The neural network, such as a multilayer perceptron, can have an input layer of source neurons, one or more computation layer(s) having one or more computation neurons, and an output layer, where there is a single output neuron for each possible category into which the input example could be classified. An input layer can have a number of source neurons equal to the number of data values in the input data. The computation neurons in the computation layer(s) can also be referred to as hidden layers, because they are between the source neurons and output neuron(s) and are not directly observed. Each neuron in a computation layer generates a linear combination of weighted values from the values output from the neurons in a previous layer, and applies a non-linear activation function that is differentiable over the range of the linear combination. The weights applied to the value from each previous neuron can be denoted, for example, by w₁, w₂, . . . wₙ₋₁, wₙ. The output layer provides the overall response of the network to the inputted data. A deep neural network can be fully connected, where each neuron in a computational layer is connected to all other neurons in the previous layer, or may have other configurations of connections between layers. If links between neurons are missing, the network is referred to as partially connected.

Training a deep neural network can involve two phases, a forward phase where the weights of each neuron are fixed and the input propagates through the network, and a backwards phase where an error value is propagated backwards through the network and weight values are updated. The computation neurons in the one or more computation (hidden) layer(s) perform a nonlinear transformation on the input data that generates a feature space. The classes or categories may be more easily separated in the feature space than in the original data space.

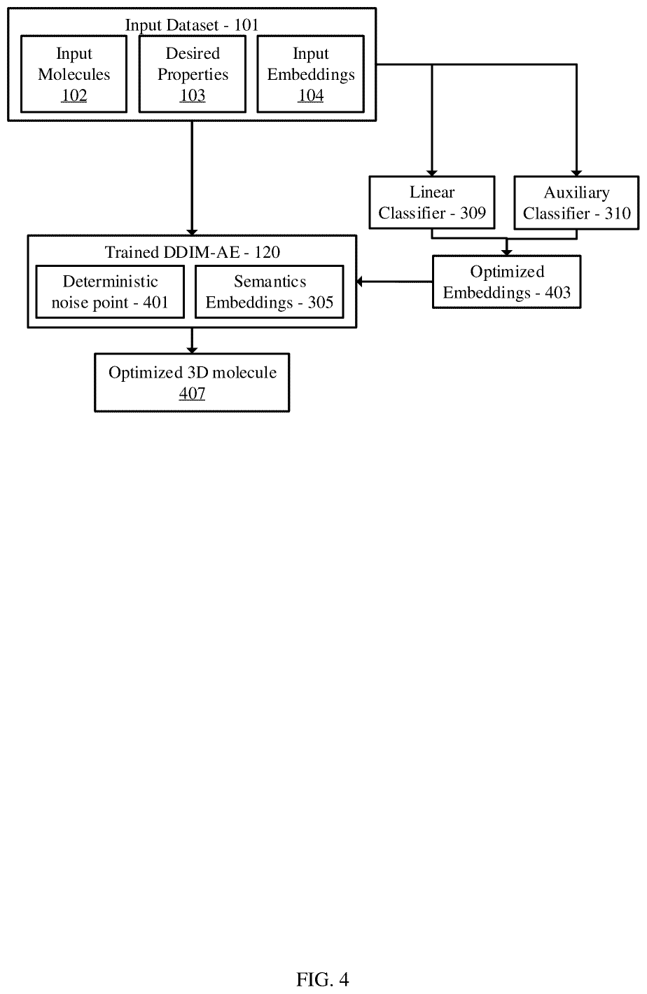

Referring now to FIG. 4, a block diagram showing hardware and software components utilized for generating an optimized three-dimensional molecule by utilizing the trained denoising diffusion implicit model autoencoder framework (DDIM-AE), in accordance with an embodiment of the present invention.

In an embodiment, during generation time (e.g., inference), an input dataset 101, including input embeddings 104, desired properties 103 and input molecules 102, can be processed to generate an optimized 3D molecule 407 having desired properties 103 based on the input molecules 102. Using the input embedding 104, the linear classifier 309 can generate optimized embeddings 403. The optimized embeddings 403 with the deterministic noise point 401 can be processed by the trained DDIM-AE 120 to generate the optimized 3D molecule 407.

In an embodiment, the input embeddings 104 can be the semantics embeddings 305 generated by the trained DDIM-AE 120 after processing the input molecules 102 from the input dataset 101.

In another embodiment, the auxiliary classifier 310 can be utilized to generate the optimized embeddings 405.

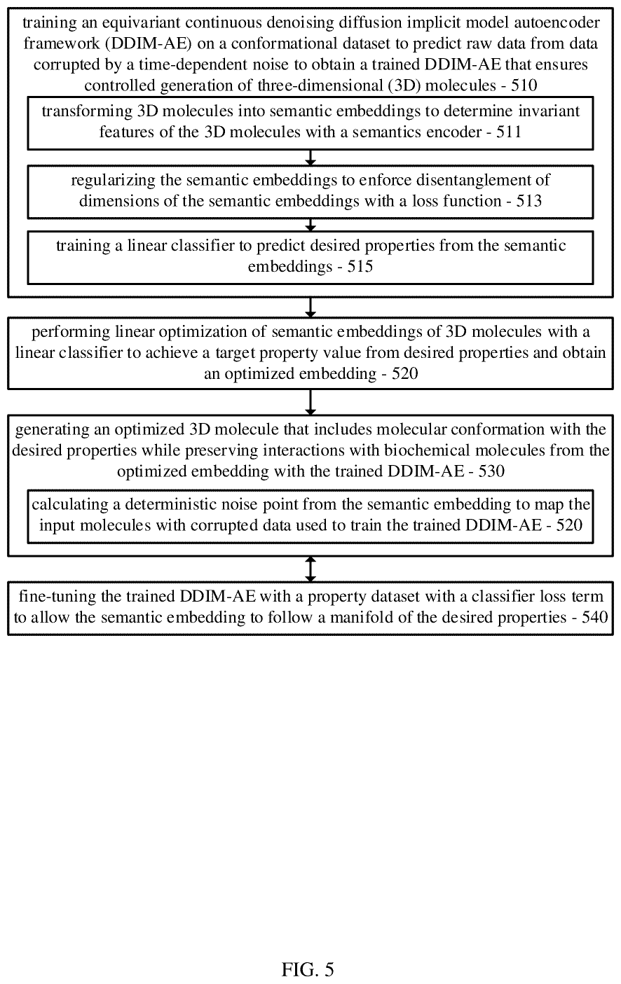

Referring now to FIG. 5, a flow diagram showing a high-level overview of a method for property guided molecular optimization using artificial intelligence diffusion models, in accordance with an embodiment of the present invention.

In an embodiment, an equivariant continuous denoising diffusion implicit model autoencoder framework (DDIM-AE) can be trained on a conformational dataset to predict raw data from data corrupted by a time-dependent noise to obtain a trained DDIM-AE that ensures controlled generation of three-dimensional (3D) molecules. Linear optimization of semantic embeddings of 3D molecules can be performed with a linear classifier to achieve a target property value from desired properties and obtain an optimized embedding. An optimized 3D molecule that includes molecular conformation with the desired properties while preserving interactions with biochemical molecules can be generated from the optimized embedding with the trained DDIM-AE.

In block 510, an equivariant continuous denoising diffusion implicit model autoencoder framework (DDIM-AE) can be trained on a conformational dataset to predict raw data from data corrupted by a time-dependent noise to obtain a trained DDIM-AE that ensures controlled generation of three-dimensional (3D) molecules.

The conformational dataset 301 includes 3D molecules 302 from an annotated molecular conformational dataset such as GEOM. A property dataset 308 can be generated from the conformational dataset 301 for fine-tuning and training of property classifiers (e.g., linear classifier 309 and auxiliary classifier 310).

To generate the property dataset 308, a cheminformatics toolkit such as RDKit™ can be utilized from the model trainer 307 to calculate the property of the validation set of the conformational dataset 301 and hold out a number (e.g., a hundred) of data points for cross-validation. The property dataset 308 can have a smaller size (e.g., ten percent smaller) compared to the conformational dataset.

In each dataset, the molecular data from the 3D molecules 302 can be represented by removing hydrogens from the molecules. Each 3D molecule can be represented as a fully-connected 3D graph x=(r, h, E), where r is the coordinates of the atoms, h is the atom type and E is the edge type. r can be centered on the center of mass (COM) of the molecule, h and E are represented by one-hot encoding. Aromatic bonds are considered a distinct type.

An E (n)-equivariant graph neural network (EGNN) can be used as the backbone both the semantic encoder 303 and the DDIM-AE 105. The DDIM-AE 105 can predict the clean data XQ from the noisy data xt (e.g., corrupted data 304).

In block 511, 3D molecules can be transformed into semantic embeddings to determine invariant features of the 3D molecules with a semantics encoder.

For the semantic encoder 303, the invariant output of the EGNN can be aggregated as the semantic embedding 305: z^{(r)}, z^{(h)}, z^{(E)}=EGNNγ(r₀, h₀, E₀) where z^{(r)} is equivariant and z^{(h)}, z^{(E)′} are invariant.

The semantic embedding 305 (z) is calculated as: z=MLP (z^{(h)}, z^{(E)}). The invariant features (e.g., atom types, edge types and pairwise distances) of the encoder output can be retained as the semantic embedding 305. For generative tasks where 3D geometry and symmetry are involved, the equivariant output could also be used.

The semantic encoder 303 can transform the raw data into the semantics embedding 305 which is updated during training. A Wasserstein loss can be applied to the embedding space to regularize its distribution and enforce disentanglement of the dimensions. Let X₀=(r₀, h₀, E₀) be an input 3D molecule, where r is the coordinate of the atom, h is the atom type and E is the edge type. The semantic encoder 303 can be implemented with an equivariant backbone that learns the conditional distribution of the semantics embedding 305 z given the input: q(z|x₀)=N(μ_{z}, σ_{z}), where μ_{z}, σ_{z}=Encoder_{γ}(x₀), z is then sampled from the distribution and provided to a diffusion “decoder” to generate a reconstruction of the input. The semantic embedding 305 (z) is treated as a condition of the diffusion process. The semantic embedding 305 (z) can be deterministically calculated from the input molecule without sampling.

In another embodiment, a variational loss (e.g., Kullback-Leibler divergence between the conditional distribution and the Gaussian distribution) or an adversarial loss (with an additional discriminator model) can be employed to regularize the distribution and enforce disentanglement of the dimensions of the embedding space of the semantic embedding 305.

The semantic embedding 305 (z) and the embedding of the time point t are concatenated to all node and edge features. \hat{r}_{0,t}, ĥ_{0,t}, Ê_{0,t}=EGNN_{θ}(rₜ, hₜ, Eₜ, z, t) The categorical values h and E are treated as multinomial Gaussian distributions of the respective dimensions.

The semantic encoder 303 can be co-trained with an auxiliary classifier 310 that predicts molecular properties y of interest from z, encouraging z to also carry information about y. To train the auxiliary classifier 310 and the linear classifier 309 a classification loss (e.g., mean squared error) can be utilized use mean squared error as the auxiliary classification loss Lcls. In another embodiment, for categorical properties, binary cross entropy can be utilized.

The DDIM-AE 105 can include a denoising diffusion probabilistic model (DDPM) with the semantics embedding 305 as the condition.

To train the DDIM-AE 105, data in the conformational dataset 301 can be corrupted by a time-dependent noise and utilized for training to predict the raw data from corrupted data 304 conditioned on the time point and the semantics embedding based on generated reconstructed 3D molecule 311.

To obtain the corrupted data 304 for training, the conditional data distribution p_{θ}(x₀|z) is approximated through a series of latent variables x₁, . . . , x_{T} with the same dimension as XQ, named the reverse process, starting from a random noise point x_{T}:

$${p}_{θ} ( {x}_{0} \vert z ) = \int p ( {x}_{T} ) {\prod }_{t = 1}^{T} {p}_{θ} ( {x}_{t - 1} \vert {x}_{t} , z ) {dx}_{1 : T} .$$

The posterior q{x_{1:T}|x_{0,z}), or the forward process gradually adds noise to Xo until it eventually becomes a random noise x_{T}:

$$q \{ {x}_{1 : T} \vert {x}_{0} , z ) = {\prod }_{t = 1}^{T} q ( {x}_{t} \vert {x}_{t - 1} , z ) .$$

The objective is to maximize the ELBO of log p(x₀)=log p(x₀|z)p(z). The random noise can include random Gaussian noises added to gradually corrupt the molecules.

Under Gaussian assumptions, it is equivalent to minimizing the prediction loss of either the clean data x₀ or ϵₜ (the noise added to x₀ at time point t) from the corrupted data 304 xₜ. Noise parametrization can be employed to achieve more stability in training. However, using clean data parametrization is more advantageous than noise parameterization, as the model is aware of the overall graph structure throughout the training.

The objective function used for training the DDIM-AE 105 can include: L=L_{D}(θ)+βL_{wass} (1), where L_{D}(θ) is the diffusion loss, L_{wass} is the Wasserstein loss and β>0 is the regularization coefficient.

The DDIM-AE 105 can be trained to predict the clean input x₀=(r₀, h₀, E₀) from corrupted data 304 xₜ=(rₜ, hₜ, Eₜ), conditioned on the embedding 305 z: \hat{r}_{0,t}, ĥ_{0,t}, Ê_{0,t}=DM_{θ}(rₜ, hₜ, Eₜ, z, t). The diffusion objective is defined as:

$${L}_{D} ( θ ) = {\sum }_{t = 1}^{T} {𝔼}_{( {r}_{0} , {h}_{0} , {E}_{0} ) , ( {\hat{r}}_{0} , {\hat{h}}_{0} , {\hat{E}}_{0} )} [ {‖ {\hat{r}}_{0 , t} - {r}_{0} ‖}_{2}^{2} + {‖ {\hat{h}}_{0 , t} - {h}_{0} ‖}_{2}^{2} + {‖ {\hat{E}}_{0 , t} - {E}_{0} ‖}_{2}^{2} ] .$$

The semantic encoder 303 and the diffusion decoder (e.g., DDIM-AE 105) are trained simultaneously on 3D molecules 302, which can be unlabeled, from the conformational dataset 301.

In block 513, the semantic embeddings can be regularized to enforce disentanglement of dimensions of the semantic embeddings with a loss function.

The semantic embedding 305 (z) can control the “direction” of the denoising (i.e. generation) towards the desired semantics. A regularization term can be implemented to enforce the maximal mutual information (MI) between the semantic embedding 305 z and the input, which empowers the semantic embedding 305 (z) to effectively guide and control the generation processes.

To control the scale and shape of the semantic embedding 305 (z), a Wasserstein loss can be employed on the marginal distribution q (z). Specifically a sample-based kernel maximum mean discrepancy on mini-batches of size n to make q (z) approach the shape of a Gaussian prior p(z)= [symbol] (0, I):

$${L}_{wass} = MMD ( q ( z ) ‖ p ( z ) ) = \frac{1}{{n}^{2}} [ {\sum }_{i \neq j} k ( {z}_{i} , {z}_{j} ) + {\sum }_{i \neq j} k ( {z}_{i}^{′} , {z}_{j}^{′} ) - 2 {\sum }_{i \neq j} k ( {z}_{i} , {z}_{j}^{′} ) ] ,$$

where 1≤i, j≤n, where k is the kernel function, zᵢ are obtained from the data points in the minibatch and zᵢ′ are randomly sampled from p(z)= [symbol] (0,I).

After training the DDIM-AE 105, the trained DDIM-AE 120 can be utilized to generate optimized 3D molecules.

In block 515, a linear classifier can be trained to predict desired properties from the semantics embeddings.

The linear classifier 309 can be utilized to perform linear optimization of the semantic embeddings 305 to achieve the target property value through training. A classification loss (e.g., mean square error) can be utilized to train the linear classifier 309. The linear classifier 309 have the same EGNN-based architecture as the semantic encoder 303, with a 2-layer MLP prediction head added on top of the model output.

To probe the information content of the semantic embedding 305, the linear classifier 309 can be trained in an unsupervised manner to predict the molecular properties from the semantic embeddings 305. For each property, a limited, distinct set of dimensions can have strong contributions. The patterns for downstream tasks can become more distinguished after fine-tuning, while the other properties remain unaffected. Both the embedding dimensions and the properties show distinct clusters by their differential contributions. Meanwhile, the dimensions have minimal internal correlations which indicate the successful disentanglement between the dimensions enforced by the Wasserstein loss.

In block 520, linear optimization of semantic embeddings of three-dimensional (3D) molecules with a linear classifier to achieve a target property value from desired properties can be performed to obtain an optimized embedding.

Given input molecule 102, the linear classifier 309 can be used to manipulate its semantic embedding 305 (or given input embeddings 104) to gain certain properties. Let xₜ be the prediction output of any denoising step, vₜ be one of (rₜ, hₜ, Eₜ), Pₘ be the set of manipulated properties, yₚ′ be the target value of property p and Ψₚ be the respective classifier, at every time step, xₜ is further updated with the classifier gradient:

$${v}_{t} ← {v}_{t} + {\sum }_{p ∈ {P}_{m}} {λ}_{p} {∇}_{{v}_{t}} {L}_{cls} ( {Ψ}_{p} ( {x}_{t} ) , {y}_{p}^{′} ) ,$$

where Δ is the guidance strength and L_{cls} is the classifier loss, which can be mean square error (MSE). The guidance strength can be a range from 0 to 1.

Given a semantic embedding 305 z, target value(s) y′, and the weight and bias of the linear regression (w, b), an optimized embedding 403 z′ can be obtained with the desired property via: z′←z+w⁺(y′−b−wz), where w⁺ is the pseudo-inverse of w, i.e. ww⁺w=w, and z′ minimizes ∥z′−z∥² subject to y′=wz′+b. The semantic embedding 305 controls the generation of the molecules to include desired properties 103 and generate optimized embedding 403. The optimized embedding 403 includes the desired property while having minimal distance from the semantic embedding 305.

In block 530, generating an optimized 3D molecule that includes molecular conformation with the desired properties while preserving interactions with biochemical molecules from the optimized embedding with the trained DDIM-AE

The trained DDIM-AE 120 can be utilized to perform downstream tasks to generate a manipulated molecule (e.g., optimized 3D molecule) with the optimized embeddings 405 and the deterministic noise point 406.

In block 531, calculating a deterministic noise point from semantic embeddings from the trained DDIM-AE.

The deterministic noise point 401 and the semantics embeddings 305 of the input molecules 102 can be obtained from the trained DDIM-AE 120.

The deterministic DDIM sampling can be utilized to calculate the deterministic noise point 401 from the semantic embedding 305. Starting from a random noise, a reconstruction of the clean data (e.g., input molecules 102 from input dataset) can be obtained by progressively removing the predicted noise deterministically:

$${v}_{t - 1} = \sqrt{{α}_{t - 1}} ( \frac{\sqrt{1 - {α}_{t} {\hat{ϵ}}_{t}^{v}}}{\sqrt{{α}_{t}}} ) + \sqrt{1 - {α}_{t - 1} {\hat{ϵ}}_{t}^{v}} ,$$

$$where$$

$${\hat{ϵ}}_{t}^{v} = \frac{1}{\sqrt{1 - {α}_{t}}} - \frac{\sqrt{{α}_{t}}}{\sqrt{1 - {α}_{t}}} {\hat{v}}_{0 , t} ,$$

vϵ(r, h, E) and \hat{v}_{0,t} is the diffusion model prediction of the clean data from xₜ and z. This could also be re-written as:

$${v}_{t - 1} = \sqrt{{α}_{t - 1}} {\hat{v}}_{0 , t} - \frac{\sqrt{1 - {α}_{t - 1}}}{\sqrt{1 - {α}_{t}}} ( \sqrt{{α}_{t}} {\hat{v}}_{0 , t} - {v}_{t} ) , \qquad ( 6 )$$

When the time step is sufficiently small, the input data (r₀, h₀, E₀) can be mapped to the noise point (r_{T}, h_{T}, E_{T}) through an inverse of the denoising process:

$${v}_{t} = \sqrt{{α}_{t - 1}} {\hat{v}}_{0 , t - 1} - \frac{\sqrt{1 - {α}_{t}}}{\sqrt{1 - {α}_{t - 1}}} ( \sqrt{{α}_{t - 1}} {\hat{v}}_{0 , t - 1} - {v}_{t - 1} ) , \qquad ( 7 )$$

The deterministic noise point 401 can be utilized to generate the optimized 3D molecule by iteratively removing noise from the generated molecule by the trained DDIM-AE 120 based on the optimized embedding 405, and obtain the optimized 3D molecule 401

The optimized embedding 405 can contain the complete information about the molecule while the optimized 3D molecule 407 can possess the properties encoded by the optimized embedding 405.

In block 540, the trained DDIM-AE can be fine-tuned on a property dataset by utilizing an auxiliary classifier with the semantics embedding.

Fine-tuning the trained DDIM-AE 120 can allow the embedding space to follow the manifold of the properties. The fine-tuned DDIM-AE 320 can either be used for linear manipulation similar to the processing of the linear classifier 309, or directly back propagate the loss of the auxiliary classifier 310 to optimize the semantic embeddings 305 to generate optimized embeddings 403.

To fine tune the trained DDIM-AE 120, the encoder and diffusion model of the trained DDIM-AE 120 from end to end with an additional classifier loss term (Lcis):

$${L}_{ft} = {L}_{D} ( θ ) + β {L}_{wass} + {β}^{′} {L}_{cls} .$$

By fine-tuning the trained DDIM-AE 120, complex properties that involve intricate interactions between the structural patterns, which cannot be learned without supervision, can be learned.

To use the auxiliary classifier to directly manipulate the embedding through iterative backpropagation, the following algorithm can be utilized:

Fine-tuning Algorithm:

z′ ← z
for i in [0, n] do
y̅ = Ψ_{cls}(z′)
L_{cls} = MSE(y̅, y′)
z′ ← z′ + λ∇_{z′}L_{cls}
end for

where λ is the learning rate and n is the number of iterations. The learning rate and number of iterations can be predetermined based on the downstream task. To decode the manipulated embedding, the clean input (e.g., input molecule 102) x₀ can be reverse-mapped to a noisy data point xₜ with the semantic embedding 305 (z).

The manipulated embedding z′ and xₜ can be fed to the diffusion decoder of the fine-tuned DDIM-AE 320 to generate an optimized 3D molecule 407.

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment. However, it is to be appreciated that features of one or more embodiments can be combined given the teachings of the present invention provided herein.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended for as many items listed.

The foregoing is to be understood as being in every respect illustrative and exemplary, but not restrictive, and the scope of the invention disclosed herein is not to be determined from the Detailed Description, but rather from the claims as interpreted according to the full breadth permitted by the patent laws. It is to be understood that the embodiments shown and described herein are only illustrative of the present invention and that those skilled in the art may implement various modifications without departing from the scope and spirit of the invention. Those skilled in the art could implement various other feature combinations without departing from the scope and spirit of the invention. Having thus described aspects of the invention, with the details and particularity required by the patent laws, what is claimed and desired protected by Letters Patent is set forth in the appended claims.

What is claimed is:

1. A method, comprising:
training an equivariant continuous denoising diffusion implicit model autoencoder framework (DDIM-AE) on a conformational dataset to predict raw data from data corrupted by a time-dependent noise to obtain a trained DDIM-AE that ensures controlled generation of three-dimensional (3D) molecules;
performing linear optimization of semantic embeddings of 3D molecules with a linear classifier to achieve a target property value from desired properties and obtain an optimized embedding; and
generating an optimized 3D molecule that includes molecular conformation with the desired properties while preserving interactions with biochemical molecules from the optimized embedding with the trained DDIM-AE.

2. The method of claim 1, further comprising notifying a decision-making entity regarding a medical diagnosis for a patient based on desired bindings from the optimized 3D molecule through automated decision making.

3. The method of claim 1, wherein training the DDIM-AE further comprises transforming 3D molecules into semantic embeddings to determine invariant features of the 3D molecules with a semantics encoder.

4. The method of claim 1, wherein training the DDIM-AE further comprises regularizing the semantic embeddings to enforce disentanglement of dimensions of the semantic embeddings with a loss function.

5. The method of claim 1, wherein training the DDIM-AE further comprises training a linear classifier to predict desired properties from the semantic embeddings.

6. The method of claim 1, wherein generating the optimized 3D molecule calculating a deterministic noise point from the semantic embedding to map input molecules with corrupted data used to train the trained DDIM-AE.

7. The method of claim 1, further comprising fine-tuning the trained DDIM-AE with a property dataset with a classifier loss term to allow the semantic embedding to follow a manifold of the desired properties.

8. A system, comprising:
a memory device;
one or more processor devices operatively coupled with the memory device to perform operations:
training an equivariant continuous denoising diffusion implicit model autoencoder framework (DDIM-AE) on a conformational dataset to predict raw data from data corrupted by a time-dependent noise to obtain a trained DDIM-AE that ensures controlled generation of three-dimensional (3D) molecules;
performing linear optimization of semantic embeddings of 3D molecules with a linear classifier to achieve a target property value from desired properties and obtain an optimized embedding; and
generating an optimized 3D molecule that includes molecular conformation with the desired properties while preserving interactions with biochemical molecules from the optimized embedding with the trained DDIM-AE.

9. The system of claim 8, further comprising notifying a decision-making entity regarding a medical diagnosis for a patient based on desired bindings from the optimized 3D molecule through automated decision making.

10. The system of claim 8, wherein training the DDIM-AE further comprises transforming 3D molecules into semantic embeddings to determine invariant features of the 3D molecules with a semantics encoder.

11. The system of claim 8, wherein training the DDIM-AE further comprises regularizing the semantic embeddings to enforce disentanglement of dimensions of the semantic embeddings with a loss function.

12. The system of claim 8, wherein training the DDIM-AE further comprises training a linear classifier to predict desired properties from the semantic embeddings.

13. The system of claim 8, wherein generating the optimized 3D molecule calculating a deterministic noise point from the semantic embedding to map input molecules with corrupted data used to train the trained DDIM-AE.

14. The system of claim 8, further comprising fine-tuning the trained DDIM-AE with a property dataset with a classifier loss term to allow the semantic embedding to follow a manifold of the desired properties.

15. A non-transitory computer program product comprising a computer-readable storage medium including a program code, wherein the program code when executed on a computer causes the computer to perform:
training an equivariant continuous denoising diffusion implicit model autoencoder framework (DDIM-AE) on a conformational dataset to predict raw data from data corrupted by a time-dependent noise to obtain a trained DDIM-AE that ensures controlled generation of three-dimensional (3D) molecules;
performing linear optimization of semantic embeddings of 3D molecules with a linear classifier to achieve a target property value from desired properties and obtain an optimized embedding; and
generating an optimized 3D molecule that includes molecular conformation with the desired properties while preserving interactions with biochemical molecules from the optimized embedding with the trained DDIM-AE.

16. The non-transitory computer program product of claim 15, further comprising notifying a decision-making entity regarding a medical diagnosis for a patient based on desired bindings from the optimized 3D molecule through automated decision making.

17. The non-transitory computer program product of claim 15, wherein training the DDIM-AE further comprises transforming 3D molecules into semantic embeddings to determine invariant features of the 3D molecules with a semantics encoder.

18. The non-transitory computer program product of claim 15, wherein training the DDIM-AE further comprises regularizing the semantic embeddings to enforce disentanglement of dimensions of the semantic embeddings with a loss function.

19. The non-transitory computer program product of claim 15, wherein training the DDIM-AE further comprises training a linear classifier to predict desired properties from the semantic embeddings.

20. The non-transitory computer program product of claim 15, wherein generating the optimized 3D molecule calculating a deterministic noise point from the semantic embedding to map input molecules with corrupted data used to train the trained DDIM-AE.
